(19) United States
(12) Patent Application Publication
(10) Pub. No.: US 2021/0313447 A1
(43) Pub. Date: Oct. 7, 2021

(54) TRANSISTOR STRUCTURE WITH SILICIDE LAYER AND FABRICATING METHOD OF THE SAME

(71) Applicant: UNITED MICROELECTRONICS CORP., Hsin-Chu City (TW)

(72) Inventor: HAO SU, Singapore (SG)

(21) Appl. No.: 16/852,539

(22) Filed: Apr. 19, 2020

(30) Foreign Application Priority Data
Apr. 1, 2020 (CN) 202010248876.3

(51) Int. Cl. H01L 29/66; H01L 21/02

(52) U.S. Cl. CPC H01L 29/66507; H01L 29/6656; H01L 29/66598; H01L 21/02334; H01L 21/0217; H01L 21/02164; H01L 29/66636

(57) ABSTRACT

A method of fabricating a transistor structure with silicide layers includes providing a substrate. A gate structure is disposed on the substrate. Two composite spacers are respectively disposed at two sides of the gate structure. Later, two source/drain doping regions are respectively formed in the substrate at two sides of the gate structure. Then, a protective material layer is formed to cover the gate structure and the two composite spacers. Subsequently, the protective material layer is etched to form two protective layers contacting the substrate and respectively covering the two composite spacers. Next, a cleaning process is performed to clean the residues from etching the protective material layer. Finally, a silicide process is performed to form numerous silicide layers respectively disposed on the source/drain doping regions outside of the protective layers and on the gate structure.

### BACKGROUND OF THE INVENTION

### 1. Field of the Invention

The present invention relates to a transistor structure with silicide layers and a method of fabricating the same, and more particularly to a transistor structure and a fabricating method which use protective layers to protect an L-shaped spacer.

### 2. Description of the Prior Art

At a deep sub-micron level of semiconductor fabrication technologies, line width, contact area, and junction depth are greatly reduced. In order to effectively enhance device performance, reduce device resistance, silicide has gradually used in the connecting parts between elements, such as a gate, source/drain doping regions or interconnects.

Before forming the silicide, a silicide block (SAB) is formed to cover the region which does not need silicide. After the SAB is patterned, there is usually a cleaning process performed. However, this cleaning process often damages the spacers on the transistor structure and leads to current leakage.

### SUMMARY OF THE INVENTION

In view of the above, it would be an advantage in the art to provide a fabricating method of a transistor structure by using a protective layer to cover an L-shaped spacer and to prevent the L-shaped spacer from being damaged during a cleaning process.

According a preferred embodiment of the present invention, a transistor structure with silicide layers includes a substrate. A gate structure is disposed on the substrate. Two composite spacers are respectively disposed at two sides of the gate structure, wherein each of the two composite spacers includes an L-shaped spacer and a main spacer, and the main spacer is disposed on the L-shaped spacer. Two protective layers contact the substrate, wherein one of the two protective layers contacts one of the two composite spacers, and the other of the two protective layers contacts the other of the two composite spacers, the main spacer and the protective layer at the same side of the gate structure respectively include a first curve and a second curve. Two source/drain doping regions are respectively disposed within the substrate at two sides of the gate structure. Two silicide layers are respectively disposed on the two source/drain doping regions outside of each of the two protective layers.

According another preferred embodiment of the present invention, a fabricating method of a transistor structure with silicide layers includes providing a substrate, wherein a gate structure is disposed on the substrate and two composite spacers are respectively disposed at two sides of the gate structure. Next, an implantation process is performed to form two source/drain doping regions respectively at two sides of the gate structure. After the implantation process, a protective material layer is formed to cover the gate structure and the two composite spacers. Later, the protective material layer is etched to form two protective layers contacting the substrate and respectively covering the two composite spacers. After forming the two protective layers, a cleaning process is performed to clean the residues from etching the protective material layer. After the cleaning process, a silicide process is performed to form a plurality of silicide layers respectively disposed on the source/drain doping regions outside of the protective layers and disposed on the gate structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 6 depict a fabricating method of a transistor structure with silicide layers according to a first preferred embodiment of the present invention, wherein:

FIG. 1 depicts a stage of providing a substrate with a gate structure thereon;

FIG. 2 is a fabricating stage following FIG. 1;

FIG. 3 is a fabricating stage following FIG. 2;

FIG. 4 is a fabricating stage following FIG. 3;

FIG. 5 is a fabricating stage following FIG. 4; and

FIG. 6 is a fabricating stage following FIG. 5.

FIG. 7 depicts an example embodiment of the present invention.

FIG. 8 to FIG. 9 depict a fabricating method of a contact plug in continuous from FIG. 6, wherein:

FIG. 8 depicts a stage of forming an interlayer dielectric; and

FIG. 9 is a fabricating stage following FIG. 8.

FIG. 10 depicts a fabricating method of a transistor structure with silicide layers according to a second preferred embodiment of the present invention.

### DETAILED DESCRIPTION

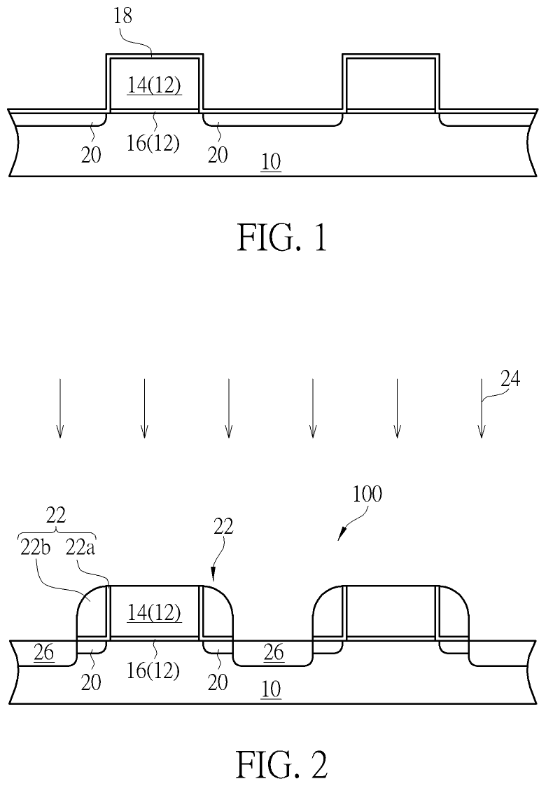

FIG. 1 to FIG. 6 depict a fabricating method of a transistor structure with silicide layers according to a first preferred embodiment of the present invention.

As shown in FIG. 1, a substrate 10 is provided. Then, a gate structure 12 is formed on the substrate 10. The gate structure 12 includes a gate electrode 14 and a gate dielectric layer 16. Later, a first spacer material layer 18 is formed conformally to cover the surface of the substrate 10 and the surface of the gate structure 12. The first spacer material layer 18 is preferably silicon oxide. Later, a lightly doped process is performed to form two lightly doping regions 20 in the substrate 10 respectively at two sides of the gate structure 12 by taking the first spacer material layer 18 and the gate structure 12 as a mask.

As shown in FIG. 2, a second spacer material layer (not shown) is formed to conformally cover the first spacer material layer 18. The second spacer material layer is preferably silicon nitride. Later, the second spacer material layer and the first spacer material layer 18 are etched to form two composite spacers 22 respectively at two sides of the gate structure 12. Each of the composite spacers 22 includes an L-shaped spacer 22a and a main spacer 22b. The L-shaped spacer 22a is formed by the first spacer material layer 18. The main spacer 22b is formed by the second spacer material layer. The L-shaped spacer 22a contacts the gate structure 12. The main spacer 22b is on the L-shaped spacer 22a. After that, an ion implantation process 24 is performed to form two source/drain doping regions 26 in the substrate 10 respectively at two sides of the gate structure 12.

As shown in FIG. 3, a first protective material layer 28 is formed to cover the gate structure 12 and the composite spacers 22. The first protective material layer 28 is preferably silicon oxide such as silicon oxide formed by a thermal process. After that, a second protective material layer 30 is formed to cover the first protective material layer 28. The second protective material layer 30 includes silicon nitride, silicon oxyntirde, silicon carbon nitride or silicon carbon oxynitride (SiOCN). The second protective material layer 30 can be formed by a deposition process.

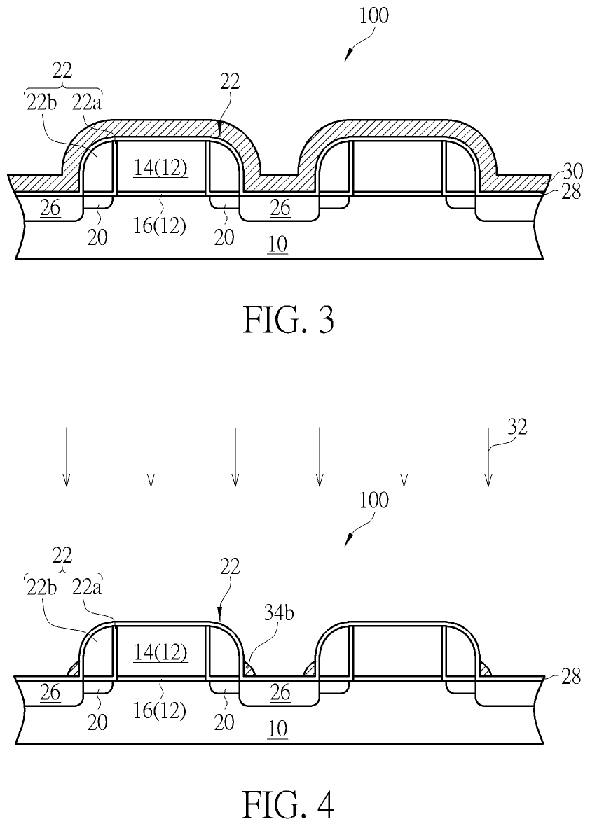

AS shown in FIG. 4, an etching process 32 is preformed to etch the second protective material layer 30 to form two second protective layers 34b respectively cover the composite spacers 22 at two side of the gate structure 12. The etching process 32 may include an isotropic etching and an anisotropic etching. By adjusting the parameters of the isotropic etching and the anisotropic etching, the height of the second protective layer 34b can be made to become smaller than one fifth of the height of the gate structure 12.

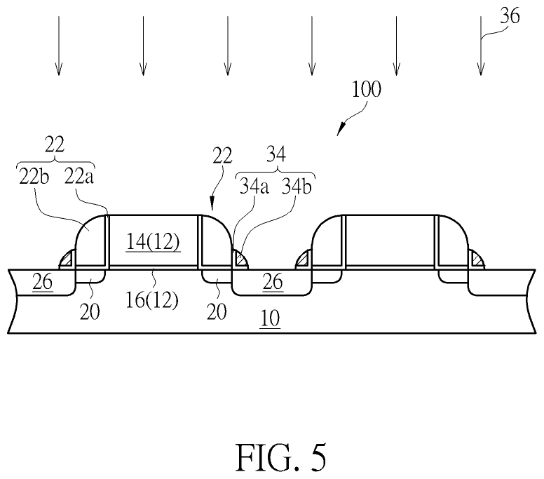

As shown in FIG. 5, a cleaning process 36 is performed to remove the residues formed by etching the second protective material layer 30. During the cleaning process 36, the first protective material layer 28 which is not covered by the second protective layer 34b is also removed to form two first protective layers 24a respectively at two side of the gate structure 12. The height of the first protective layer 34a is the same as the height of the second protective layer 34b. The first protective layer 34a and the second protective layer 34b at the same side of the gate structure 12 form a protective layer 34. The protective layer 34 at least entirely covers the end of the L-shaped spacer 22a close to the top surface of the substrate 10. The height the protective layer 34 is preferably smaller than one-fifth of the height of the gate structure 12. A thickness of the protective layer 34 is smaller than one-tenth of the height of the gate structure 12. According to different requirements, the height and the thickness of the protective layer 34 can be adjusted, and not limited to the range mentioned above. Furthermore, the cleaning process 36 is preferably performed by using diluted hydrogen fluoride (Diluted HF).

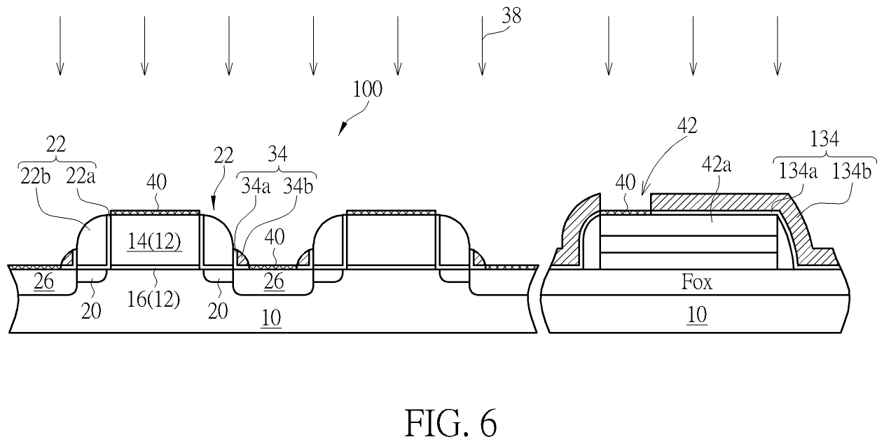

As shown in FIG. 6, after the cleaning process 36, a silicide process 38 is performed to form several silicide layers 40 respectively on the source/drain doping regions 26 outside of the protective layer 34 and on the gate structure 12. Now, a transistor structure 100 of the present invention is completed. It is noteworthy that the protective layers 34 are formed simultaneously with the silicide block (SAB) 134. The material for forming the protective layer 34 is the same as the material for forming the SAB 134. For example, as shown in FIG. 6, a capacitor structure 42 is disposed on the substrate 10. The SAB 134 covers part of the capacitor structure 42. The SAB 134 includes a first block layer 134a and a second block layer 134b. The first block layer 134a and the first protective layer 34a are formed by the same material layer at the same step. Later, the first block layer 134a and the first protective layer 34a are patterned by the same clean process 36 shown in FIG. 5. The second block layer 134b and the second protective layer 34b are formed by the same material layer at the same step. Then, the second block layer 134b and the second protective layer 34b are etched in the same etching process 32 shown in FIG. 4 to form patterned profiles. After the SAB 134 and the protective layer 34 are formed, the silicide process 38 is performed to form the silicide layer 40 on part of the capacitor top electrode 42a, and on the source/drain doping regions 26 and the gate structure 12 by taking the SAB 134 as a mask.

As a result, the protective layers 34 are formed at the same step for forming the SAB 134. Therefore, there is no extra process added. Moreover, the source/drain doping regions 26 and the lightly doped regions 20 are formed before forming the protective layer 34. In other words, there is not any ion implantation process performed after forming the protective layers 34 until the silicide process 40 is completed. That is, after forming the protective layers 34, there is no doping region is formed in the substrate 10 at two sides of the gate structure 12, and the protective layers 34 do not serve as a mask layer for an ion implantation process.

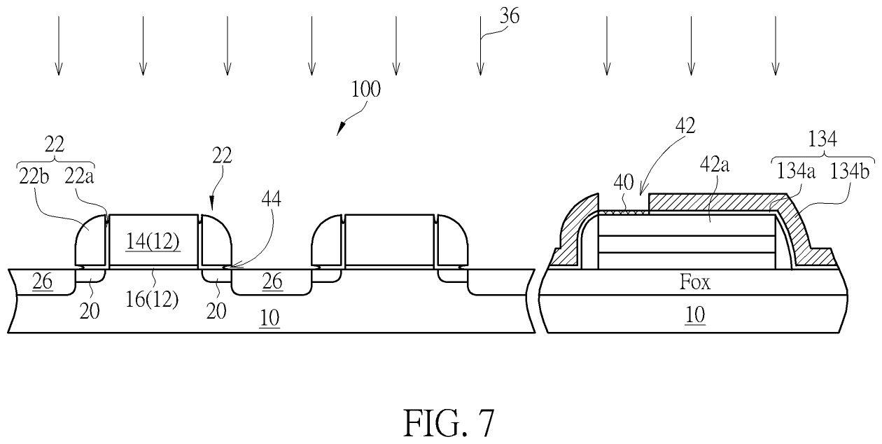

FIG. 7 depicts an example embodiment of the present invention, wherein elements in FIG. 7 which are substantially the same as those in the first preferred embodiment are denoted by the same reference numerals; an accompanying explanation is therefore omitted. FIG. 7 is the step in continuous of the step of FIG. 2. FIG. 7 shows after forming the source/drain doping regions 26, the SAB 134 is formed without keeping/forming the protective layer 134. Therefore, the end of the L-shaped spacer 22a close to the subtract 10 is not covered by the protective layer 34. In other words, the SAB 134 in FIG. 7 only to separate the silicide regions and non-silicide regions. The SAB 134 does not serve as the protective layer 34. As mentioned above, the step of forming the SAB 134 includes the etching process 32 and the cleaning process 36. However, during the cleaning process 36, the cleaning solution etches the ends of the L-shaped spacer 22a and leads to a recess 44. The recess 44 on the end of the L-shaped spacer 22a close to the substrate 10 results in current leakage in the transistor structure 100 formed afterwards. On the other hands, the protective layer 34 in the first preferred embodiment protects the L-shaped spacer 22a during the etching process 36, prevents the end of the L-shaped spacer 22a from being etched and current leakage can be avoided.

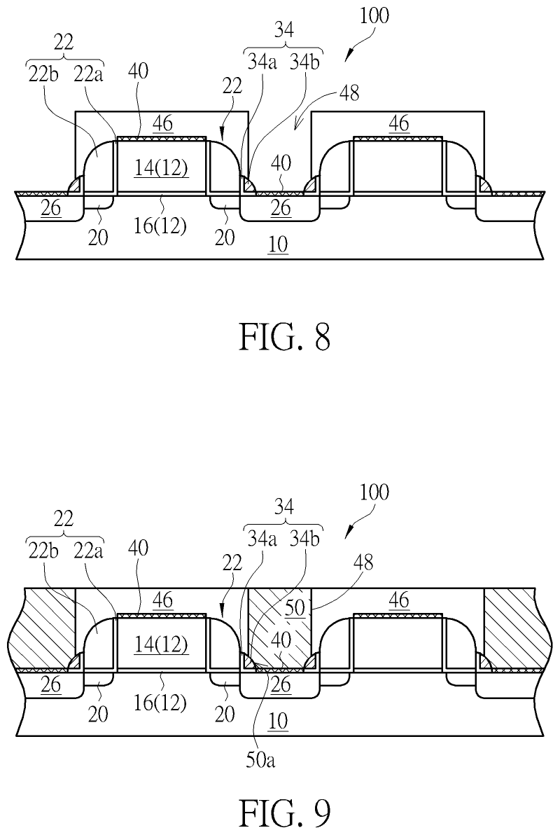

FIG. 8 to FIG. 9 depict a fabricating method of a contact plug in continuous from FIG. 6. As shown in FIG. 8, an interlayer dielectric 46 is formed to cover the substrate 10 and the transistor structure 100. Later, the interlayer dielectric 46 is etched to remove part of the interlayer dielectric 46 along the profile of the protective layer 34. In this way, the contact hole 48 penetrating the interlayer dielectric 46 and exposing the silicide layer 40 is formed. As shown in FIG. 9, a contact plug 50 is filled in the contact hole 48 to contact the silicide layer 40. It is noteworthy that an end of the contact plug 50 close to the substrate 10 has two concaved curves 50a. These concaved curves 50a is formed because of the protective layer 34. The contact plug 50 may be metal or alloy such as tungsten, copper, aluminum or other conductive materials.

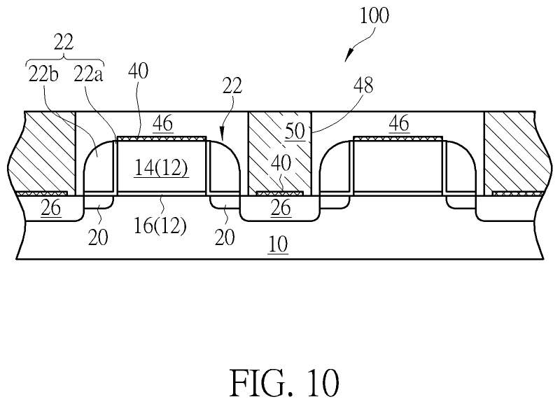

FIG. 10 depicts a fabricating method of a transistor structure with silicide layers according to a second preferred embodiment of the present invention, wherein elements in FIG. 10 which are substantially the same as those in the first preferred embodiment are denoted by the same reference numerals; an accompanying explanation is therefore omitted. FIG. 10 is steps following FIG. 6. As shown in FIG. 10, after forming the silicide layers 40, completely removing the protective layers 34 to expose the source/drain doping regions 26 entirely. Later, an interlayer dielectric 46 is formed to cover the substrate 10 and the transistor structure 100. The interlayer dielectric 46 also contacts part of the source/drain doping regions 26. Then, a contact plug 50 is formed to penetrate the interlayer dielectric 46 and contact the silicide layer 40 and the source/drain doping regions 26. It is noteworthy that the middle of the end of the contact plug 50 contacts the silicide layer 40, and the edge of the end of the contact plug 50 contacts the source/drain doping regions 26.

FIG. 6 depicts a transistor structure fabricated by the first preferred embodiment of the present invention. As shown in FIG. 6, a transistor structure 100 includes a substrate 10. A gate structure 12 is disposed on the substrate 10. Two composite spacers 22 respectively disposed at two side of the gate structure 12. Each of the composite spacers 22 includes an L-shaped spacer 22a and a main spacer 22b. The main spacer 22b is disposed on the L-shaped spacer 22a. The L-shaped spacer 22a includes silicon oxide and the main spacer 22b includes silicon nitride. Two protective layers 34 contact the substrate 10 and respectively contact each of the composite spacers 22. Each of the protective layers 34 includes a first protective layer 34a and a second protective layer 34b. Each of the first protective layers 34a contacts one of the composite spacers 22. The second protective layer 34b is disposed on the first protective layer 34a. The first protective layer includes silicon oxide. The second protective material layer 30 includes silicon nitride, silicon oxyntirde, silicon carbon nitride or silicon carbon oxynitride (SiOCN). The main spacer 34b and the protective layer 34 at the same side of the gate structure 12 respectively include a first curve and a second curve. The first curve and the second curve form a wave-like profile. Two source/drain doping regions 26 are disposed in the substrate 10 at two sides of the gate structure 12. The source/drain doping regions 26 can be N-type doping regions or P-type doping regions. Two silicide layers 40 are respectively on the source/drain doping regions 26 outside of each protective layer 34. The silicide layers 40 include NiSi₂, WSi₂, CoSi₂, TiSi₂ or other metal silicide. Furthermore, there is no silicide layer 40 directly under the protective layers 34. Each of the composite spacers 22 includes a surface, and at least half of the surface is not covered by the protective layers 34.

Because there are generally numerous transistor structures 100 disposed adjacent to each other on the substrate 10. Two adjacent transistor structures 100 share one source/drain doping region 26. Therefore, the protective layers 34 on each of the adjacent transistor structures 100 influence the size of the contact area between the contact plug 50 and the shared source/drain doping region 26. According to a preferred embodiment of the present invention, a height of each of the protective layers 34 is smaller than one-fifth of a height of the gate structure 12. A thickness of each of the protective layers 34 is smaller than one-tenth of the height of the gate structure 12. In this way, the L-shaped spacer 22a can be effectively protected, and the size of the contact plug of the contact plug 50 can also be controlled in a sufficient range.

The transistor structure in FIG. 10 is a varied type of the transistor structure in FIG. 6. The differences between the transistor structure in FIG. 10 and the transistor structure in FIG. 6 is that there is no protective layer 34 on the transistor structure 100 in FIG. 10; therefore the contact plug 50 contacts both the silicide layer 40 and the source/drain doping region 26. In this way, the sheet resistance between the contact plug 50 and the source/drain doping region 26 is decreased.

Those skilled in the art will readily observe that numerous modifications and alterations of the device and method may be made while retaining the teachings of the invention. Accordingly, the above disclosure should be construed as limited only by the metes and bounds of the appended claims.

1: A transistor structure with silicide layers comprising:
a substrate;
a gate structure disposed on the substrate;
two composite spacers respectively disposed at two sides of the gate structure, wherein each of the two composite spacers comprises an L-shaped spacer and a main spacer, and the main spacer is disposed on the L-shaped spacer;
two protective layers contacting the substrate, wherein one of the two protective layers contacts one of the two composite spacers, and the other of the two protective layers contacts the other of the two composite spacers, the main spacer and the protective layer at the same side of the gate structure respectively comprise a first curve and a second curve;
two source/drain doping regions respectively disposed within the substrate at two sides of the gate structure; and
two silicide layers respectively disposed on the two source/drain doping regions outside of each of the two protective layers.

2: The transistor structure with silicide layers of claim 1, wherein a height of each of the protective layers is smaller than one-fifth of a height of the gate structure.

3: The transistor structure with silicide layers of claim 1, wherein a thickness of each of the protective layers is smaller than one-tenth of a height of the gate structure.

4: The transistor structure with silicide layers of claim 1, wherein each of the composite spacers comprises a surface, and at least half of the surface is not covered by the two protective layers.

5: The transistor structure with silicide layers of claim 1, wherein the L-shaped spacer contacts the gate structure.

6: The transistor structure with silicide layers of claim 1, wherein the two protective layers comprise silicon oxide or silicon nitride.

7: The transistor structure with silicide layers of claim 1, wherein the first curve and the second curve form a wave-like profile.

8: A fabricating method of a transistor structure with silicide layers, comprising:
providing a substrate, wherein a gate structure is disposed on the substrate, two composite spacers are respectively disposed at two sides of the gate structure;
performing an implantation process to form two source/drain doping regions respectively at two sides of the gate structure;
after the implantation process, forming a protective material layer to cover the gate structure and the two composite spacers;
etching the protective material layer to form two protective layers contacting the substrate and respectively covering the two composite spacers;
after forming the two protective layers, performing a cleaning process to clean the residues from etching the protective material layer; and
after the cleaning process, performing a silicide process to form a plurality of silicide layers respectively disposed on the source/drain doping regions outside of the protective layers and disposed on the gate structure.

9: The fabricating method of the transistor structure with silicide layers of claim 8, wherein a height of each of the protective layers is smaller than one-fifth of a height of the gate structure.

10: The fabricating method of the transistor structure with silicide layers of claim 8, wherein a thickness of each of the protective layers is smaller than one-tenth of a height of the gate structure.

11: The fabricating method of the transistor structure with silicide layers of claim 8, wherein each of the composite spacers comprises an L-shaped spacer and a main spacer, the L-shaped spacer comprises an end close to a surface of the substrate, and the end is not removed during the cleaning process.

12: The fabricating method of the transistor structure with silicide layers of claim 8, wherein each of the composite spacers comprises a surface, and at least half of the surface is not covered by the two protective layers.

13: The fabricating method of the transistor structure with silicide layers of claim 8, wherein after forming the two protective layers and before forming the silicide layers, there is not any ion implantation process is performed.
